(19) United States
(12) Patent Application Publication
(10) Pub. No.: US 2026/0072109 A1
(43) Pub. Date: Mar. 12, 2026

(54) Method for Reconstructing a Time Series of Magnetic Resonance Datasets for Water Fat Separation Based on the Dixon Method

(71) Applicant: Siemens Healthineers AG, Forchheim (DE)

(72) Inventors: Christian Meixner, Erlangen (DE); Marcel Dominik Nickel, Herzogenaurach (DE); Adam Kettinger, Erlangen (DE)

(73) Assignee: Siemens Healthineers AG, Forchheim (DE)

(21) Appl. No.: 19/325,632

(22) Filed: Sep. 11, 2025

(30) Foreign Application Priority Data
Sep. 12, 2024 (DE) 10 2024 208 673.8

(51) Int. Cl. G01R 33/48; G01R 33/54; G01R 33/56; G01R 33/565

(52) U.S. Cl. CPC G01R 33/4828; G01R 33/543; G01R 33/5608; G01R 33/56563

(57) ABSTRACT

The disclosure relates to a computer-implemented method for reconstructing a time series of magnetic resonance datasets for the purpose of water-fat separation based on the Dixon method, wherein a magnetic resonance dataset comprises complex image data acquired for at least two different echo times. The method comprises (a) determining one or more phase maps of the phase errors induced in the complex image data due to B0 field inhomogeneities for the two or more magnetic resonance datasets acquired at different time points, wherein the determining comprises a phase unwrapping which is conducted taking into account all the magnetic resonance datasets of the time series; and (b) calculating fat and/or water images from the magnetic resonance datasets for the time series that have been corrected by means of the phase map(s). The disclosure also relates to a computer program and a computer, e.g. a control computer of an MRT apparatus.

### CROSS-REFERENCE TO RELATED APPLICATIONS

The present application claims priority to and the benefit of Germany patent application no. DE 10 2024 208 673.8, filed on Sep. 12, 2024, the contents of which are incorporated herein by reference in their entirety.

### TECHNICAL FIELD

The disclosure relates to a computer-implemented method for reconstructing a time series of two or more magnetic resonance datasets acquired at different time points during an examination of a subject for the purpose of water-fat separation based on the Dixon method. The disclosure also relates to a computer program and a computer, e.g. a control computer of a magnetic resonance tomography apparatus.

### BACKGROUND

Magnetic resonance (MR) images of the human or animal body generally contain signals both of water and of fat. In order to visualize these tissue types differently in the image, use can be made of the fact that water and fat have slightly different resonant frequencies, i.e. a chemical shift with a difference of approx. 3.4 ppm. This can be used for example to suppress the fat signal by means of a frequency-selective pulse. However, this is difficult, especially at lower field strengths, since the difference in the chemical shift then becomes too small in terms of absolute numbers. Another possible method for separating the fat signal from the water signal is the Dixon technique. This entails conducting scans in which the magnetic resonance signal is acquired at different echo times. The different echo times lead to a phase difference between fat signal and water signal. In an ideal example, the echo times could be chosen for example such that fat signal and water signal have the same phase at a first echo time and a phase that is different by π at a second echo time. In this case, the images can then be combined in the course of a postprocessing step to generate a fat image and a water image.

In the process, however, phase ambiguities must be removed and the actual phase characteristic reconstructed so that fat and water can be correctly separated. For instance, there exists the problem that small inhomogeneities in the B0 field already lead to such great phase shifts that the phases of the fat signal and water signal vary over the image, and furthermore also beyond the maximum resolvable limit of +π and −π. This leads to phase ambiguities due to the fact that each time when the phase exceeds the +π or −π, it wraps itself, i.e. jumps from +π to −π and the other way round. This is also referred to as “phase wrap”. In Dixon imaging, different methods are therefore applied for phase unwrapping in which the phase ambiguities are removed. Comparable methods are known for example in the article by Jingfei Ma “Dixon Techniques for Water and Fat Imaging”, Journal of Magnetic Resonance Imaging 28:543-558 (2008), Holger et al. “Dual-echo Dixon Imaging with Flexible Choice of Echo Times”, Magn. Reson. Med. 65(1): 96-107 (2001), or also in the article by Johann Berglund et al. “Two-point Dixon Method with Flexible Echo Times”, Magnetic Resonance in Medicine 65:994-1004 (2011). By means of these techniques it is possible to estimate the correct phase characteristic within an image and thus conduct a phase correction of the acquired Dixon images.

The Dixon technique is also frequently used in time-resolved MR acquisitions. In this case, MR images are acquired for example prior to, during, and after contrast agent administration to enable the inflow of the contrast agent into the tissue to be observed. Since, for example, malignant tumors accumulate contrast agent particularly quickly, this can help in identifying and localizing such tumors with maximum precision. In this case a fat image and/or water image can be generated for each MR acquisition and the respective fat images and/or water images of the time series are subtracted from one another. The inflow effect of the contrast agent is particularly clearly recognizable on these difference images.

Conventionally, the phase correction is performed individually for each time point. This also makes sense since the B0 field inhomogeneities which cause the phase errors, triggered by movement of the patient, may be different between the individual time points.

### SUMMARY

In spite of sophisticated phase unwrapping techniques, artifacts occasionally occur in MR images acquired using the Dixon technique, and in particular in dynamic MR image acquisitions. The disclosure has therefore set itself the object of improving the Dixon technique even further.

The object is aimed at even further reducing artifacts induced due to B0 field inhomogeneities. The disclosure achieves this object via the various aspects as described herein, including the claims.

According to a first aspect, the disclosure provides a computer-implemented method for reconstructing a time series of two or more magnetic resonance datasets acquired at different time points during an examination of a subject for the purpose of water-fat separation based on the Dixon method, wherein a magnetic resonance dataset comprises complex image data, wherein the method comprises the following steps:
(a) determining one or more phase maps of the phase errors induced in the complex image data due to B0 field inhomogeneities for the two or more magnetic resonance datasets acquired at different time points, wherein the determination step comprises a phase unwrapping which is performed taking into account all the magnetic resonance datasets of the time series;
(b) calculating fat images and/or water images from the magnetic resonance datasets corrected by means of the phase map(s) for the time series.

The Dixon methods are based on the assumption that the B0 field drifts slightly over the field of view. For this reason, the magnetic resonance datasets, which contain complex image data, are reconstructed using a model which includes the water signal, the fat signal, and also a background phase (called a phase error in this context). Conventionally, the background phase is determined independently for each time point of a time series, as a result of which artifacts can be generated at the individual time points. According to the disclosure, the background phase is now determined in a correlated manner for all time points, and artifacts are avoided as a result.

The disclosure therefore solves the described problem in that the phase maps of the phase errors induced in the image data of a time series due to B0 field inhomogeneities are determined from magnetic resonance datasets with the aid of a phase unwrapping process which is performed taking into account all the magnetic resonance datasets of the time series. In other words—unlike in the conventional approach—a separate phase map which is independent of the phase maps of the other magnetic resonance datasets of the time series is not determined for each magnetic resonance dataset of the time series. Rather, the phase information of the different time points is combined for processing. The disclosure has namely recognized that artifacts in the above-described subtraction images can be induced due to slight fluctuations in the B0 field between the individual time points, for example due to movement, pulsation or for other physiological reasons. This can then lead to a situation in which the phase unwrapping yields different results in succeeding images, and this can lead to artifacts e.g. in subtraction images of a measurement series.

The phase unwrapping is often conducted on the assumption that the spatial variation in the phase information is weak. It has been shown that this assumption is also helpful for the time dimension and leads to a reduction in artifacts. That is, it is important that the phase errors in the phase information of the magnetic resonance datasets acquired at different time points are corrected collectively. It has been shown that this results in fewer artifacts being induced within a time series. This becomes particularly clear when the fat and/or water images of the time series are compared with one another, e.g. are subtracted from one another to generate subtraction images.

The subject may e.g. be a human being or animal, e.g. a patient. The MR datasets can be acquired of any part of the anatomy, for example the skull, abdomen, heart, lung, liver or limbs.

A magnetic resonance dataset for water-fat separation based on the Dixon method is understood to mean a dataset which has been acquired in the course of an imaging magnetic resonance examination. The MR dataset permits the water signal and fat signal to be separated based on their different phases. Such an MR dataset can contain data acquired at a number of different echo times. A magnetic resonance dataset for water-fat separation based on the Dixon method is also referred to in the following as a “magnetic resonance dataset”, “MR dataset”or also “Dixon dataset”.

A time series is understood in this context to mean a series of two or more magnetic resonance datasets acquired at different time points by means of the Dixon method. The time series may contain any suitable number of images such as for instance 2-50, 10- 30, etc., images of the subject. These may e.g. be acquired directly one after the other, i.e. during the same examination of the subject. The magnetic resonance datasets may e.g. be image datasets, also referred to in the following as images. All the magnetic resonance datasets may for instance be acquired using the same parameters, e.g. using the same field of view and using the same acquisition parameters. However, a time series can also relate to an arrangement of different image contrasts, such as different inversion times, for example. In this case at least some of the magnetic resonance datasets of the time series are acquired using different acquisition parameters, for example using different inversion times. By this means it is possible to acquire image datasets using a combination of T1 mapping and Dixon in which the Dixon method is used separately for different inversion times.

According to an embodiment, the subject is injected with a contrast agent, e.g. a gadolinium-containing contrast agent, at the start of the time series. In this case reference is also made to DCE (dynamic contrast enhanced) imaging. In an aspect, this allows the perfusion to be examined. DCE is based on the T1-shortening effect of gadolinium-based contrast agents. In this case, for example, a bolus of the contrast agent is injected intravenously and thereafter a rapid time series of T1-weighted MR images is acquired. Regionally increased signal indicates a concentration of the contrast agent, which in turn is indicative for example of an increased perfusion or also a permeability of the tissue into the extravascular space.

Within the time series, the individual magnetic resonance datasets may be acquired at any suitable time resolution such as e.g. a time resolution of 2-20 seconds, 5-10 seconds, etc., per image. At the same time, sequence types of different speeds can be used, e.g. gradient echo sequences. For example, a spoiled gradient echo sequence of the “VIBE” type can be used. Each magnetic resonance dataset may e.g. contain image data acquired at at least two different echo times. In an embodiments, said data may be acquired at precisely two different echo times (2-point Dixon technique), though it is also possible to measure at three different echo times (3-point Dixon technique). Furthermore, the method according to the disclosure can also be performed using magnetic resonance datasets acquired at just one echo time, i.e. using the so-called “1-point Dixon technique”.

The method according to the disclosure comprises determining one or more phase maps of phase errors induced in the complex image data due to B0 field inhomogeneities for the two or more magnetic resonance datasets acquired at different time points for the purpose of water-fat separation based on the Dixon method, wherein the determination comprises a phase unwrapping which is performed taking into account all the magnetic resonance datasets of the time series. The determination of the phase map or maps includes determining the phase errors induced in the complex image data due to B0 field inhomogeneities. Because the determination is performed taking into account all the magnetic resonance datasets of the time series, fluctuations in the B0 field between the individual time points are also taken into account commensurately, e.g. in the phase unwrapping. According to the disclosure, the phase information of the respective time points is also processed in a combined manner. Changes in the B0 field between the individual time points can be compensated for in this way.

The phase maps can be determined by means of known methods, as described for example in the above-cited articles by Ma et al., Eggers et al. or Berglund et al. Ma et al. describes different possible methods. In one example, a phase correction algorithm is used which for instance determines the phase error in the form of a phase vector. A region-growing method is used in this case. These and other methods are based on minimizing a cost function. In this case for example minimum-norm methods or path-following methods can be used for the phase unwrapping.

Determining the phase maps comprises a phase unwrapping. What is meant by this is the handling of the phase ambiguities which result due to the fact that the phase of the complex image data can have a maximum value of +π to −π.

Once one or more phase maps have been determined taking into account all the magnetic resonance datasets of the time series, fat and/or water images are calculated from the magnetic resonance datasets for the time series that have been corrected by means of the phase maps. In an aspect, water images can be calculated, which then advantageously show the inflow of any contrast agent. For instance, a water image and/or fat image are/is then calculated for each complex dataset of the time series.

According to an embodiment, the one or more phase maps for the different time points are determined on the assumption that the phase errors change only weakly over time, e.g. the phase maps being averaged or smoothed across the time series. This assumption has the advantage that sudden jumps in the phase characteristic over time are avoided. It has been shown that this reduces the susceptibility to artifacts, for instance in subtraction images. The assumption is based among other things on the patient not moving or moving only a little between the individual acquisitions of the time series, such that the B0 field inhomogeneities also change only slightly. It is therefore possible to calculate the phase maps for the different time points by means of the different methods described here, by means of which the complex image data and/or the phase maps are smoothed or averaged across the time series. As a result, the phase can be homogenized across the different time points and artifacts in the subtraction image of two time points can be avoided.

According to an advantageous embodiment, the one phase map is determined in that the magnetic resonance datasets are averaged over the different time points and a phase map is determined from the complex image data of the averaged magnetic resonance dataset, and wherein said phase map is used to calculate the fat and/or water images for the entire time series.

With this embodiment, therefore, only a single phase map is used for the correction of the magnetic resonance datasets. This is determined in that the magnetic resonance datasets acquired at the different time points are averaged. The averaging can determine for example the arithmetic mean over the time dimension for each pixel. A phase map is then determined—by means of the known phase unwrapping methods—from the averaged magnetic resonance dataset. This phase map is then used for the entire time series, although the fat and/or water images are determined with the aid of said phase map from the unaveraged magnetic resonance datasets. As a result, the image information is preserved, though the phase correction is advantageously homogenized over time. As well as reducing artifacts, this has the advantage that the calculation time for the phase maps is reduced. In addition to avoiding artifacts, a reduction in computing time is therefore also achieved.

According to an advantageous embodiment, the one or more phase maps are determined in that a phase map is determined for each magnetic resonance dataset of the different time points and the phase maps of the different time points are averaged in order to obtain an averaged phase map or are smoothed over time in order to obtain a smoothed phase map for each time point, the averaged phase map or the smoothed phase maps being used for the calculation of the fat and/or water images.

In this embodiment, a phase map is initially determined in the known manner for each magnetic resonance dataset of the time series. Then, the phase maps of the different time points are averaged in order to obtain a single averaged phase map. The arithmetic mean can also be used once again here. Alternatively, the phase maps of the different time points are smoothed over time in order to obtain a smoothed phase map for each time point. The B0 field changes between the individual time points are likewise compensated for by this means and artifacts avoided as a result. The phase map averaged in this way or the smoothed multiple phase maps are then used for the water-fat separation for the individual time points.

According to an advantageous embodiment, the multiple phase maps are determined in that the magnetic resonance datasets are low-pass filtered over the different time points and a phase map is determined for each time point from the magnetic resonance dataset low-pass filtered in the time dimension, the fat and/or water images being determined e.g. from the unfiltered magnetic resonance datasets corrected by means of these phase maps.

In this embodiment, the two or more magnetic resonance datasets are low-pass filtered in the time dimension. The window of the low-pass filter can be divided such that for example up to e.g. 5 successive magnetic resonance datasets contribute at all times. Any jumps in the phase information are smoothed as a result. A low-pass filtered magnetic resonance dataset is therefore determined for each time point. From this, the phase map used for the correction is then determined. However, to ensure the image information remains as correct as possible, the phase maps are not used for correcting the low-pass filtered magnetic resonance datasets, but for correcting the unfiltered magnetic resonance datasets. The averaging is therefore carried out solely for the purpose of the phase correction across the time series, while the fat and/or water images are determined from the unfiltered magnetic resonance datasets. The image information is preserved as a result, though the phase correction is advantageously homogenized over time.

According to an advantageous embodiment, the multiple phase maps are determined from the complex image data of the magnetic resonance datasets using multidimensional phase unwrapping, wherein the time is one dimension of the phase unwrapping. According to this embodiment, the phase unwrapping is also performed in the temporal direction in addition to the spatial direction. Determining the phase maps by phase unwrapping within the framework of the Dixon method is based namely on the assumption that the spatial variation in the phase information is weak. This is equally justifiable for the temporal dimension. Accordingly, the phase unwrapping in this embodiment can be extended in such a way that time is a (further) dimension of the phase unwrapping. In this embodiment, the phase unwrapping is not limited to discrete values. Advantageously, this can also produce a smoothing. For the phase unwrapping, for example, the methods referenced in the aforementioned articles by Eggers et al., Ma et al. and Berglund et al. can be cited. In an aspect, the phase unwrapping methods can be based on methods such as region growing, for example in conjunction with minimum gradient or minimum variance methods. This entails for example selecting one pixel and the region is then grown by incorporating the neighboring pixel having the best quality value.

According to an advantageous embodiment, an additional step (c) of calculating subtraction images from the fat and/or water images of the magnetic resonance datasets corrected by means of the one or more phase maps is performed across the time series. These subtraction images show for example the inflow of a contrast agent injected at the start or before the start of the time series. In an aspect, the subtraction images are calculated in each case by subtracting the first water image and/or fat image of the time series from the second and each further water image and/or fat image. This allows the changes compared to the first image to be visualized particularly clearly. Within the context of the DCE, for example, this permits the assessment of suspect nodes since these accumulate a contrast agent more quickly.

According to an embodiment, the method also includes a step of acquiring a time series of magnetic resonance datasets for water-fat separation based on the Dixon method. In an aspect, the magnetic resonance datasets are acquired of a part of the body of a subject, e.g. a patient. The acquisition is performed in the course of an examination conducted by means of a magnetic resonance tomography (MRT) apparatus.

According to a further aspect, the disclosure is also directed to a computer program comprising software code sections which cause a computer to perform the method according to the disclosure when the software code sections are executed on the computer. The software code sections can be programmed in any desired programming language, e.g. in a programming language which can be converted by a control computer of an MRT apparatus.

The disclosure is also directed to a digital storage medium containing a corresponding computer program. The digital storage medium can be any desired data storage medium, for example an optical, magnetic or solid-state storage medium. By way of example, the storage medium may be a hard disk, a cloud computer, an SD card, an SSD card, a USB stick, or a CD-ROM.

According to a further aspect, the disclosure is also directed to a computer which is e.g. a control computer of a magnetic resonance tomography apparatus. The computer comprises: an input interface for receiving a time series of two or more magnetic resonance datasets acquired at different time points during an examination of a subject for water-fat separation based on the Dixon method, wherein a magnetic resonance dataset comprises complex image data, as well as a processor unit which is configured to perform the method according to the disclosure. The computer is connected e.g. to an MRT apparatus or is a part of the same.

The processor unit can be any desired computing unit, e.g. a CPU or GPU. However, the method according to the disclosure can also be performed on a portable computer, for example a laptop, tablet, or on a mobile terminal device such as a smartphone. Furthermore, the method according to the disclosure can also be performed on a cloud computer. It is possible for instance following the acquisition of the complex magnetic resonance datasets, to export them to a remote computer, for example via an internet connection, and to evaluate them there. The fat and/or water images can then be provided by said remote computer and if necessary displayed and/or diagnostically interpreted at yet a third location.

According to an embodiment, the processor unit is configured to calculate subtraction images from the fat and/or water images of the magnetic resonance datasets corrected by means of the one or more phase maps across the time series, wherein the computer further comprises an output interface for outputting and/or displaying the subtraction images. This advantageously permits the subtraction images determined according to the disclosure to be displayed and immediately evaluated.

According to a further aspect, the disclosure is also directed to a magnetic resonance tomography apparatus comprising the computer according to the disclosure. In other respects, the magnetic resonance tomography apparatus (MRT apparatus) can be equipped in the conventional manner.

All features and advantages cited with reference to the method can also be applied to the computer program, the digital storage medium and the computer, and vice versa.

### BRIEF DESCRIPTION OF THE DRAWINGS

The disclosure will now be described in more detail with the aid of exemplary embodiments and with reference to the attached drawing. In the drawings:

FIG. 1 illustrates an exemplary embodiment of an MRT apparatus according to the disclosure;

FIG. 2 illustrates a flowchart of an exemplary embodiment of a method according to the disclosure; and

FIG. 3 illustrates an exemplary illustration of a combined phase unwrapping.

### DETAILED DESCRIPTION OF THE DISCLOSURE

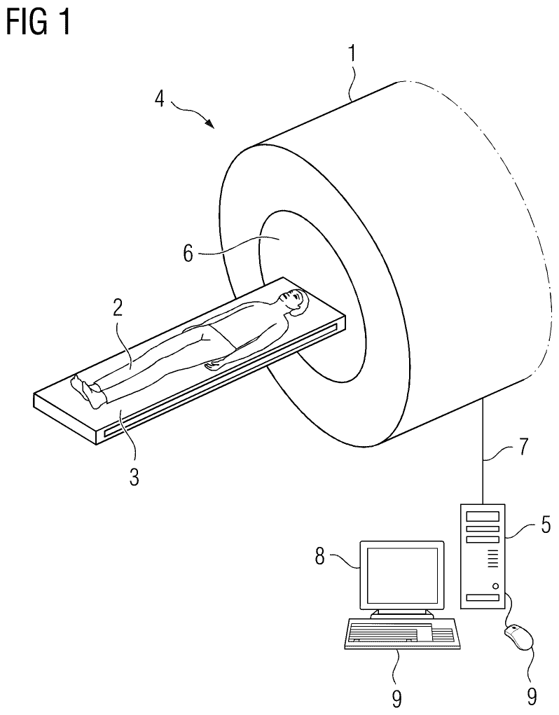

FIG. 1 illustrates sections of an MRT apparatus 4 according to an embodiment of the disclosure. The MRT apparatus 4 is designed to acquire magnetic resonance images of a patient 2. For this purpose, the patient 2 is introduced on a motorized couch 3 into the tunnel 6 of the main magnet 1. The main magnet generates the B0 field, i.e. the main magnetic field, which typically ranges between 0.5 T and 7 T, more particularly from 1.5 T to 3 T. Further important components (not shown) such as gradient coils and a radiofrequency coil for receiving the MR signal are also arranged inside the main magnet 1. A time series of Dixon image datasets of the patient 2 can be acquired. The MRT apparatus is controlled by the computer 5 during this process. The complex image data of the Dixon images can be transferred via an interface 7 to the computer 5, which is embodied to perform the method according to the disclosure. For this purpose, a corresponding computer program product can be installed on the computer 5. The fat and/or water images or subtraction images can be displayed on a screen 8. The computer 5 additionally has input devices 9 in the form of mouse and keyboard.

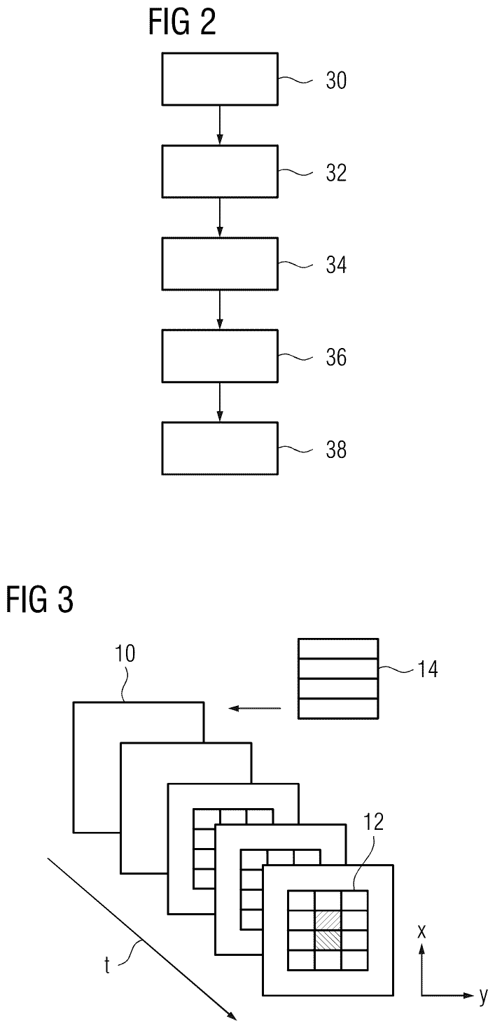

FIG. 2 illustrates a flowchart of an embodiment of the method according to the disclosure. In step 30, a time series of two or more magnetic resonance datasets of a subject is acquired for fat-water separation based on the Dixon method, e.g. in the course of an MRT examination. The magnetic resonance datasets comprise complex image data acquired e.g. at least two different echo times. In step 32, one or more phase maps of the phase errors induced in the complex image data due to B0 field inhomogeneities are calculated from said data. This is realized using one of the phase unwrapping methods described here while taking into account all the magnetic resonance datasets of the time series. The thus calculated one or more phase maps are then used in step 34 for calculating fat and/or water images. In step 36, the fat and/or water images are processed further, e.g. subtraction images of the time series being calculated, by subtracting the first water image or fat image of the time series in each case. In step 38, the thus determined subtraction images are displayed, for example on a screen 8.

FIG. 3 schematically illustrates a series of two-dimensional phase maps 10 over time t, said phase maps 10 having been generated from a corresponding time series of two-dimensional magnetic resonance datasets 14. By using a suitable data model it is possible to calculate corresponding phase maps 10 from the complex image data of the magnetic resonance datasets 14. According to an embodiment, said phase maps 10 are then subjected to a phase unwrapping not only in the two dimensions x, y of the image plane but also in the time dimension t. This can be performed for example by means of a pixel-wise region growing method, as indicated at 12.

Additionally, the various components described herein may be referred to as “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units, as applicable and relevant, may alternatively be referred to herein as “circuitry,” “controllers,” “processors,” or “processing circuitry,” or alternatively as noted herein.

What is claimed is:

1. A computer-implemented method for reconstructing a time series of two or more magnetic resonance datasets, comprising:
acquiring the time series of the two or more magnetic resonance datasets at different time points during an examination of a subject for water-fat separation based on the Dixon method, the two or more magnetic resonance datasets comprising complex image data acquired during at least two different echo times;
determining one or more phase maps of the phase errors induced in the complex image data due to B0 field inhomogeneities for the two or more magnetic resonance datasets, the determination comprising a phase unwrapping that is performed by taking into account the two or more magnetic resonance datasets of the time series; and
calculating fat and/or water images from the two or more magnetic resonance datasets that have been corrected via the one or more phase maps for the time series.

2. The method as claimed in claim 1, wherein the one or more phase maps are determined by performing averaging or smoothing across the time series.

3. The method as claimed in claim 1, wherein the one or more phase maps are determined by averaging the magnetic resonance datasets over the different time points, and determining the one or more phase maps from the complex image data of the averaged magnetic resonance dataset; and
calculating the fat and/or water images for the time series using the one or more phase maps.

4. The method as claimed in claim 1, wherein the one or more phase maps are determined by, for each of the two or more magnetic resonance datasets, averaging the one or more phase maps to obtain an averaged phase map, and
wherein the fat and/or water images are calculated based on the averaged phase map.

5. The method as claimed in claim 1, wherein the one or more phase maps are determined by, for each of the two or more magnetic resonance datasets, smoothing the one or more phase maps to obtain a smoothed phase map, and
wherein the fat and/or water images are calculated based on the smoothed phase map.

6. The method as claimed in claim 1, wherein the one or more phase maps are determined by performing a low-pass filtering of the two or more magnetic resonance datasets over the different time points, and determining the one or more phase maps for each time point from the low-pass filtered two or more magnetic resonance dataset in the time dimension, and
wherein the fat and/or water images are calculated from unfiltered magnetic resonance datasets that have been corrected via the one or more phase maps.

7. The method as claimed in claim 1, wherein the one or more phase maps are determined from the complex image data of the two or more magnetic resonance datasets using multidimensional phase unwrapping, and
wherein time is one dimension of the phase unwrapping.

8. The method as claimed in claim 1, further comprising:
calculating subtraction images from the fat and/or water images of the two or more magnetic resonance datasets.

9. A control computer of a magnetic resonance tomography apparatus, comprising:
an input interface configured to receive a time series of two or more magnetic resonance datasets that have been acquired at different time points during an examination of a subject for water-fat separation based on the Dixon method,
wherein the two or more magnetic resonance datasets comprise complex image data acquired during at least two different echo times,
a processor configured to:
determine one or more phase maps of the phase errors induced in the complex image data due to B0 field inhomogeneities for the two or more magnetic resonance datasets by performing a phase unwrapping taking into account the two or more magnetic resonance datasets of the time series; and
calculate fat and/or water images from the two or more magnetic resonance datasets that have been corrected via the one or more phase maps for the time series.

10. The control computer as claimed in claim 9, wherein the processor is configured to calculate subtraction images from the fat and/or water images of the two or more magnetic resonance datasets, and further comprising:
an output interface configured to output and/or display the subtraction images.

11. A non-transitory computer-readable medium having instructions stored thereon that, when executed by one or more processors of a magnetic resonance tomography apparatus, cause the magnetic resonance tomography apparatus to:
receive a time series of two or more magnetic resonance datasets that have been acquired at different time points during an examination of a subject for water-fat separation based on the Dixon method,
wherein the two or more magnetic resonance datasets comprise complex image data acquired during at least two different echo times,
determine one or more phase maps of the phase errors induced in the complex image data due to B0 field inhomogeneities for the two or more magnetic resonance datasets by performing a phase unwrapping taking into account the two or more magnetic resonance datasets of the time series; and
calculate fat and/or water images from the two or more magnetic resonance datasets that have been corrected via the one or more phase maps for the time series.
